(19) United States
(12) Patent Application Publication
(10) Pub. No.: US 2018/0166621 A1
(43) Pub. Date: Jun. 14, 2018

(54) VEHICLE BATTERY THERMOELECTRIC DEVICE WITH INTEGRATED COLD PLATE ASSEMBLY

(71) Applicant: Gentherm Inc., Northville, MI (US)

(72) Inventors: Marco Ranalli, Augsburg (DE); Martin Adldinger, Holzheim (DE); Alexander Strobl, Genderkingen (DE); Dumitru-Cristian Leu, Freising (DE)

(21) Appl. No.: 15/580,543

(22) PCT Filed: Jun. 8, 2016
(86) PCT No.: PCT/US2016/036444

§ 371 Date: Dec. 7, 2017

Related U.S. Application Data
(60) Provisional application No. 62/173,500, filed on Jun. 10, 2015.

(51) Int. Cl. H01L 35/30; F25B 21/02; H01L 35/32; H01M 10/6572; H01M 10/625

(52) U.S. Cl. CPC H01L 35/30; F25B 21/02; H01L 35/32; H01M 10/6572; B60L 2210/10; F25B 2321/023; F01N 2240/02; F01P 2050/24; H01M 10/625

(57) ABSTRACT

A cooling system for thermally conditioning a component which includes a heat spreader and a thermoelectric device that operatively thermally engages the heat spreader. A cold plate assembly operatively thermally engages the thermoelectric device. A fastening element secures the cold plate assembly to the heat spreader to provide a clamp load on the thermoelectric device and the cold plate assembly, wherein the thermoelectric device and the cold plate assembly are integrated with one another as a module.

### CROSS-REFERENCE TO RELATED APPLICATIONS

This application claims priority to U.S. Provisional Application No. 62/173,500, which was filed on Jun. 10, 2015 and is incorporated herein by reference.

### BACKGROUND

This disclosure relates to a module used to cool a vehicle component, such as a battery. In particular, the disclosure relates to an integrated thermoelectric device and cold plate assembly that provides the module.

Lithium ion batteries are used in passenger and other types of vehicles to provide power to electric motors that provide propulsion to the vehicle. Such batteries can generate a significant amount of heat such that the battery must be cooled to prevent performance degradation.

One type of vehicle battery cooling arrangement that has been proposed that includes a thermoelectric module arranged beneath the battery and adjacent to a cold plate assembly. The thermoelectric module includes thermoelectric devices that operate based upon the Peltier effect to provide cooling adjacent to the battery. Heat transferred through the thermoelectric device is rejected to the cold plate assembly, which may have a cooling fluid circulated therethrough and sent to a heat exchanger.

It is desirable to design the cooling arrangement so as to efficiently transfer heat through some components within the cooling arrangement while insulating other components within the cooling arrangement.

### SUMMARY

In one exemplary embodiment, a cooling system for thermally conditioning a component which includes a heat spreader and a thermoelectric device that operatively thermally engages the heat spreader. A cold plate assembly operatively thermally engages the thermoelectric device. A fastening element secures the cold plate assembly to the heat spreader to provide a clamp load on the thermoelectric device and the cold plate assembly, wherein the thermoelectric device and the cold plate assembly are integrated with one another as a module.

In a further embodiment of the above, the fastening element is provided by multiple threaded fasteners.

In a further embodiment of any of the above, the fasteners are secured through holes in an interior of the cold plate assembly.

In a further embodiment of any of the above, the fasteners are secured through holes in a flange at a perimeter of the cold plate assembly.

In a further embodiment of any of the above, the cold plate assembly includes a central portion and first and second manifolds that are arranged to provide fluid passages. The central portion supports the thermoelectric device.

In a further embodiment of any of the above, the central portion is extruded to provide multiple passages.

In a further embodiment of any of the above, the central portion is constructed from an aluminum.

In a further embodiment of any of the above, the first and second manifolds include an inner perimeter that is arranged about an outer perimeter of the central portion in a sleeved arrangement.

In a further embodiment of any of the above, the central portion includes bends to accommodate the first and second manifolds such that the first and second manifolds are flush with a heat transfer surface of the central portion.

In a further embodiment of any of the above, the heat spreader includes a perimeter that has a lip that extends to circumscribe a perimeter of the cold plate assembly.

In a further embodiment of any of the above, the heat spreader is constructed from an aluminum.

In a further embodiment of any of the above, multiple thermoelectric devices are mounted to the cold plate assembly.

In a further embodiment of any of the above, the thermoelectric devices are Peltier devices.

In a further embodiment of any of the above, thermal foils are provided between the Peltier devices and the cold plate assembly.

In a further embodiment of any of the above, an insulator plate is supported by the heat spreader and surrounds the thermoelectric devices.

In a further embodiment of any of the above, a cooling loop that includes a heat exchanger is in fluid communication with the cold plate assembly.

In a further embodiment of any of the above, a battery is supported on the heat spreader.

In a further embodiment of any of the above, a DC/DC converter is arranged in operative thermal engagement with the cold plate assembly.

### BRIEF DESCRIPTION OF THE DRAWINGS

The disclosure can be further understood by reference to the following detailed description when considered in connection with the accompanying drawings wherein:

FIG. 1 is a highly schematic view of a vehicle with a vehicle system temperature regulated by a cooling system.

FIG. 2 is an exploded perspective view of a thermoelectric device and cold plate assembly.

FIG. 3 is schematic cross-sectional view of the thermoelectric device and cold plate assembly shown in FIG. 2.

FIG. 4A is an elevational view of an example cold plate assembly.

FIG. 4B is a cross-sectional view of the cold plate assembly shown in FIG. 4A and taken along line 4B-4B.

FIG. 4C is a cross-sectional view of the cold plate assembly shown in FIG. 4A and taken along line 4C-4C.

The embodiments, examples and alternatives of the preceding paragraphs, the claims, or the following description and drawings, including any of their various aspects or respective individual features, may be taken independently or in any combination. Features described in connection with one embodiment are applicable to all embodiments, unless such features are incompatible.

### DETAILED DESCRIPTION

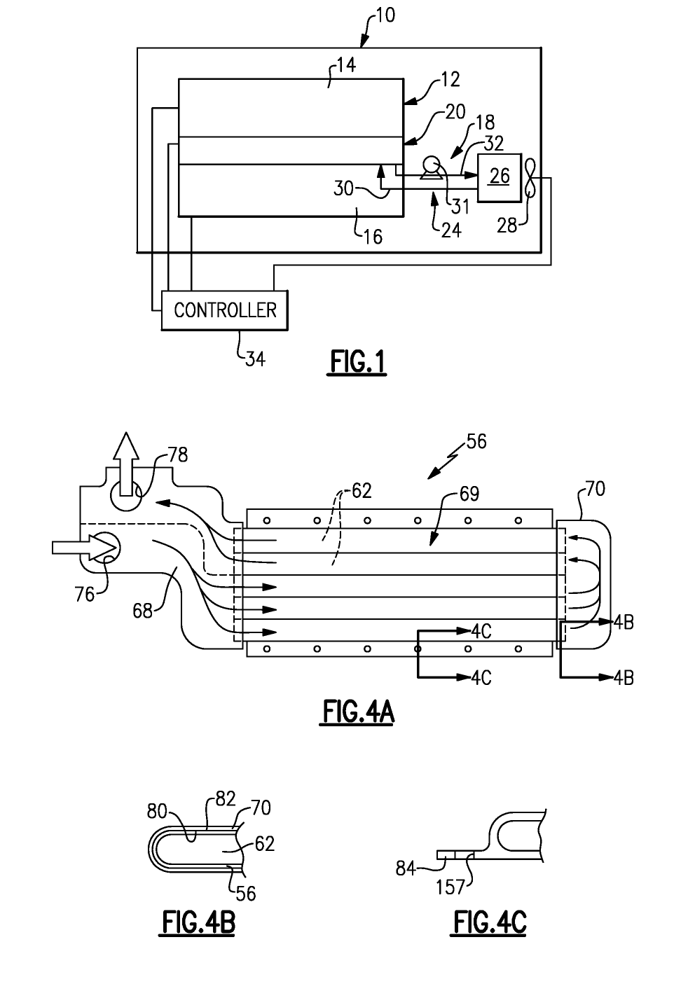

A vehicle 10 is schematically illustrated in FIG. 1A. The vehicle 10 includes a vehicle system 12 that either needs to be heated or cooled. In one example, the vehicle system 12 includes a battery 14, such as a lithium ion battery used for vehicle propulsion that generates a significant amount of heat. Such a battery must be cooled during operation otherwise the battery efficiency and/or integrity may degrade.

A cooling system 18 is arranged between the battery 14 and a DC/DC converter 16 in a stack to remove heat from the battery 14 thus cooling the vehicle system 12. The DC/DC converter 16 provides an electrical interface between the battery 14 and the vehicle electrics. A cooling system 18 includes an integrated thermoelectric device and cold plate assembly module 20 that is in communication with a cooling loop 24. A cooling fluid, such as glycol, is circulated by a pump 31 within the cooling loop 24. Heat is rejected to the coolant via a cold plate assembly 56 (FIG. 2) through supply and return coolant lines 30, 32 that are connected to a heat exchanger 26. A fan or blower 28 may be used to remove heat from the coolant within the heat exchanger 26 to an ambient environment, for example.

A controller 34 communicates with various components of the vehicle 10, vehicle system 12 and cooling system 18 to coordinate battery cooling. Sensors and outputs (not shown) may be connected to the controller 34.

An example module 20 is shown in more detail in FIG. 2. The module 20 provides a cold side 38 that supports a surface of the battery 14. The cold plate assembly 56 provides a hot side 40 that is in operative thermal engagement with the DC/DC converter 16.

In the example module 20, a heat spreader 46 provides the cold side 38 and is constructed of an aluminum or other material with a relatively high heat transfer coefficient. Multiple thermoelectric devices 54, such as Peltier devices, are in thermal engagement with the heat spreader 46. In the example, four Peltier devices are wired in series with one another. A cold plate assembly 56 has a surface 58 that is in thermal engagement with the thermoelectric devices 54 on a side opposite the heat spreader 46 to provide the hot side 40 at surface 60.

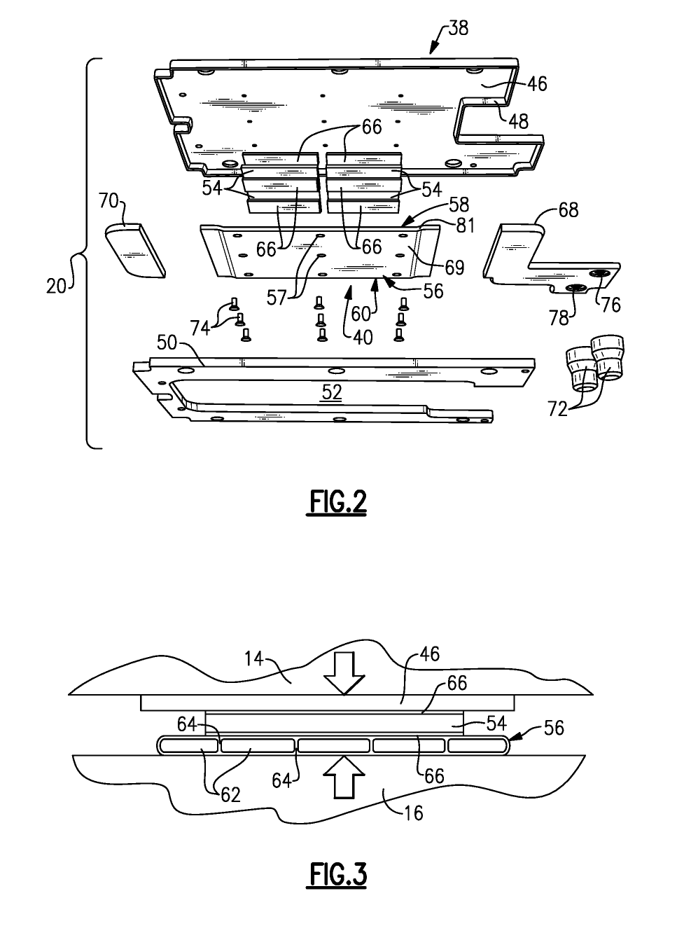

The cold plate assembly 56 includes a central portion 69 and first and second manifolds 68, 70 arranged to provide fluid passages 62, as shown in FIGS. 3 and 4A. The central portion 69 supported the thermoelectric devices 54. The central portion 69 may be extruded from aluminum for strength to provide multiple passages 62 separated by walls 64, as shown in FIG. 3. The first manifold 68 provides an inlet 76 and an outlet 78 connected to fluid fittings 72 (FIG. 2) that are coupled to the cooling loop 24. The first and second manifolds 68, 70 may be constructed from a molded plastic, or a metal such as aluminum if it is desirable to also use the manifolds for heat transfer purposes, as described below.

The central portion 69 includes bends 81 to accommodate the first and second manifolds 68, 70 such that the first and second manifolds are flush with a heat transfer surface 60 of the central portion 69, as best shown in FIG. 2. As a result, the manifolds may also be arranged in intimated contact with the DC/DC converter 16 to further enhance heat transfer between the cold plate assembly 56 and the DC/DC converter. As shown in FIGS. 4A and 4B, the first and second manifolds 68, 70 include an inner perimeter 80 arranged about an outer perimeter 82 of the central portion 69 in a sleeved or nested arrangement to achieve the flush surfaces.

Returning to FIG. 2, fastening elements, such as threaded fasteners 74, are used to secure the cold plate assembly 56 to the heat spreader 46 to a predetermined torque, for example, to provide a clamp load on the thermoelectric device 54 (arrows in FIG. 3). In the example shown in FIG. 2, the fasteners 74 are secured through holes 57 (not shown in FIG. 4A) arranged at an interior of the central portion 69. In the example shown in FIGS. 4A and 4C, the fasteners 74 (not shown) are also secured through holes 157 in a flange 84 (not shown in FIG. 2) arranged at a perimeter of the cold plate assembly 56. Using fasteners 74 at the interior of the central portion 69 may provide a better clamp load on the thermoelectric devices 54, which provides improved thermal communication between the thermoelectric devices 54 and the heat spreader 46 and cold plate assembly 56. Thermal foils 66 may be provided on the thermoelectric devices 54 to further enhance thermal communication and accommodate any tolerance stack ups, as shown in FIG. 3.

An insulator plate 50 is supported by the heat spreader 46 and surrounds the thermoelectric devices 54, which are arranged within an aperture 52 in the insulator plate 50. The heat spreader 46 includes a perimeter having a lip 48 that extends to circumscribe and protect a perimeter of the cold plate assembly 56. A seal (not shown) may be arranged between the lip 48 and the DC/DC converter 16 to enclose the cavity containing the thermoelectric devices 54 and thermally isolate the heat spreader 46 from the DC/DC converter 16.

The heat spreader 46 and the cold plate assembly 56 are secured to one another to provide an integrated module that provides the clamp load to the thermoelectric devices 54. The insulator plate 50 can be secured to the heat spreader 46 or other structure independently of the thermoelectric devices 54. Without a metallic bottom heat spreader arranged opposite the heat spreader 46, heat can be transferred more efficiently and directly to structures such as the DC/DC converter 16. The module 20 also simplifies assembly of the stack and reduces cost.

In operation, an undesired battery temperature is detected by the controller 34. The thermoelectric devices 50 are powered to produce a cold side of the thermoelectric device 54 that is transferred to the first heat spreader 46 adjacent to the battery 14 increasing the temperature differential between these components and increasing the heat transfer therebetween. Heat from the battery is transferred from the heat spreader 46 through the thermoelectric device 54 directly to the cold plate assembly 56 in the case of the example thermoelectric module assembly 20 shown in FIGS. 2-3. However, the isolator plate 50 acts to prevent heat from being transmitted from the heat spreader 46 to the DC/DC converter 16. Heat is also rejected from the DC/DC converter 16 to the cold plate assembly 56. Coolant is circulated from the cold plate assembly 56 to the heat exchanger 26, which rejects heat to the ambient environment, and this heat transfer rate may be increased by use of the blower 28.

It should be understood that although a particular component arrangement is disclosed in the illustrated embodiment, other arrangements will benefit herefrom. Although particular step sequences are shown, described, and claimed, it also should be understood that steps may be performed in any order, separated or combined unless otherwise indicated and will still benefit from the present invention.

Although the different examples have specific components shown in the illustrations, embodiments of this invention are not limited to those particular combinations. It is possible to use some of the components or features from one of the examples in combination with features or components from another one of the examples.

Although an example embodiment has been disclosed, a worker of ordinary skill in this art would recognize that certain modifications would come within the scope of the claims. For that reason, the following claims should be studied to determine their true scope and content.

What is claimed is:

1. A cooling system for thermally conditioning a component, the cooling system comprising:
a heat spreader;
a thermoelectric device operatively thermally engaging the heat spreader;
a cold plate assembly operatively thermally engaging the thermoelectric device; and
a fastening element securing the cold plate assembly to the heat spreader to provide a clamp load on the thermoelectric device and the cold plate assembly, wherein the thermoelectric device and the cold plate assembly are integrated with one another as a module.

2. The cooling system according to claim 1, wherein the fastening element is provided by multiple threaded fasteners.

3. The cooling system according to claim 2, wherein the fasteners are secured through holes in an interior of the cold plate assembly.

4. The cooling system according to claim 2, wherein the fasteners are secured through holes in a flange at a perimeter of the cold plate assembly.

5. The cooling system according to claim 1, wherein the cold plate assembly includes a central portion and first and second manifolds arranged to provide fluid passages, the central portion supporting the thermoelectric device.

6. The cooling system according to claim 5, wherein the central portion is extruded to provide multiple passages.

7. The cooling system according to claim 6, wherein the central portion is constructed from an aluminum.

8. The cooling system according to claim 5, wherein the first and second manifolds include an inner perimeter arranged about an outer perimeter of the central portion in a sleeved arrangement.

9. The cooling system according to claim 8, wherein the central portion includes bends to accommodate the first and second manifolds such that the first and second manifolds are flush with a heat transfer surface of the central portion.

10. The cooling system according to claim 1, wherein the heat spreader includes a perimeter having a lip that extends to circumscribe a perimeter of the cold plate assembly.

11. The cooling system according to claim 10, wherein the heat spreader is constructed from an aluminum.

12. The cooling system according to claim 1, wherein multiple thermoelectric devices are mounted to the cold plate assembly.

13. The cooling system according to claim 12, wherein the thermoelectric devices are Peltier devices.

14. The cooling system according to claim 13, wherein thermal foils are provided between the Peltier devices and the cold plate assembly.

15. The cooling system according to claim 12, wherein an insulator plate is supported by the heat spreader and surrounds the thermoelectric devices.

16. The cooling system according to claim 1, comprising a cooling loop that includes a heat exchanger in fluid communication with the cold plate assembly.

17. The cooling system according to claim 16, comprising a battery supported on the heat spreader.

18. The cooling system according to claim 17, comprising a DC/DC converter arranged in operative thermal engagement with the cold plate assembly.
